(19) United States
(12) Patent Application Publication
(10) Pub. No.: US 2019/0067095 A1
(43) Pub. Date: Feb. 28, 2019

(54) LAYER FORMING METHOD

(71) Applicant: ASM IP Holding B.V., Almere (NL)

(72) Inventors: Chiyu Zhu, Helsinki (FI); Kiran Shrestha, Phoenix, AZ (US); Qi Xie, Leuven (BE); Bhushan Zope, Phoenix, AZ (US)

(21) Appl. No.: 16/117,530

(22) Filed: Aug. 30, 2018

Related U.S. Application Data
(63) Continuation-in-part of application No. 15/691,241, filed on Aug. 30, 2017.
(60) Provisional application No. 62/607,070, filed on Dec. 18, 2017.

(51) Int. Cl. H01L 21/768; C23C 16/455; C23C 16/448

(52) U.S. Cl. CPC H01L 21/76876; H01L 21/76877; C23C 16/448; C23C 16/45527; C23C 16/45553

(57) ABSTRACT

There is provided a method of forming a layer, comprising depositing a seed layer on the substrate; and depositing a bulk layer on the seed layer. Depositing the seed layer comprises supplying a first precursor comprising metal and halogen atoms to the substrate; and supplying a first reactant to the substrate. Depositing the bulk layer comprises supplying a second precursor comprising metal and halogen atoms to the seed layer; and, supplying a second reactant to the seed layer.

### CROSS-REFERENCE TO RELATED PATENT APPLICATIONS

The present application is a continuation-in-part of U.S. Non-Provisional application Ser. No. 15/691,241, filed on Aug. 30, 2017 and entitled “LAYER FORMING METHOD,” and claims the benefit of U.S. Provisional Patent Application No. 62/607,070, filed on Dec. 18, 2017 and entitled “LAYER FORMING METHOD,” both of which are incorporated herein by reference.

### FIELD

The present disclosure generally relates to a method to form a layer on a substrate. More particularly, the disclosure relates to sequentially repeating an atomic layer deposition (ALD) cycle or a chemical vapor deposition (CVD) process to form at least a part of the layer on a substrate with gaps created during manufacturing of a feature. The layer on the substrate may be used for manufacturing of a semiconductor device.

### BACKGROUND

In atomic layer deposition (ALD) and chemical vapor deposition (CVD), a substrate is subjected to a first precursor and a first reactant suitable for reacting into a desired layer on the substrate. The layer may be deposited in a gap created during manufacturing of a feature on the substrate to fill the gap.

In ALD, the substrate is exposed to a pulse of the first precursor and a monolayer of the first precursor may be chemisorbed on the surface of the substrate. The surface sites may be occupied by the whole of or by a fragment of the first precursor. The reaction may be chemically self-limiting because the first precursor will not adsorb or react with the portion of the first precursor that has already been adsorbed on the substrate surface. The excess of the first precursor is then purged, for example, by providing an inert gas and/or removing the first precursor from a reaction chamber. Subsequently, the substrate is exposed to a pulse of the first reactant, which chemically reacts with the adsorbed whole or fragment of the first precursor until the reaction is complete and the surface is covered with a monolayer of the reaction product.

It has been found that there may be a need to improve the quality of the deposited layers.

### SUMMARY

There may be a need for an improved method to form a deposited layer on a substrate. Accordingly, there may be provided a method of forming a layer, comprising: providing a substrate with gaps created during manufacturing of a feature and depositing a seed layer on the substrate; and depositing a bulk layer on the seed layer. Depositing the seed layer may comprise: supplying a first precursor comprising metal and halogen atoms to the substrate; and supplying a first reactant to the substrate, wherein a portion of the first precursor and the first reactant react to form at least a portion of the seed layer. Depositing the bulk layer may comprise: supplying a second precursor comprising metal and halogen atoms to the seed layer; and, supplying a second reactant to the seed layer, wherein a portion of the second precursor and the second reactant react to form at least a portion of the bulk layer on the seed layer. The first and second precursor may be different.

By having different first and second precursor for the seed layer and the bulk layer the properties of the seed layer and the bulk layer may be optimized such that the quality of the total layer may be improved. The first and second reactant may be the same and comprise hydrogen atoms.

In some other embodiments, a method for semiconductor processing is provided. The method includes depositing a metal layer into a gap in the substrate, thereby filling the gap.

### BRIEF DESCRIPTION OF THE DRAWINGS

These and other features, aspects, and advantages of the invention disclosed herein are described below with reference to the drawings of certain embodiments, which are intended to illustrate and not to limit the invention.

FIGS. 1a and 1b show a flowchart illustrating a method of depositing a layer according to an embodiment.

FIG. 2 shows a cross-section of a gap structure on a substrate filled with a layer according to an embodiment.

### DETAILED DESCRIPTION

A metal layer may be required as a conducting layer in a semiconductor device. Gaps created during manufacturing of a feature of an integrated circuit device may be filled with metal layers. The gaps may have a high aspect ratio in that their depth is much larger than their width.

The gaps may be extending vertically in already manufactured layers having a substantially horizontal top surface. Gaps in a vertical direction and filled with a metal may, for example, be used in a word line of a memory integrated circuit of the dynamic random access memory (DRAM) type. Gaps in a vertical direction and filled with a metal may, for example, also be used in a logic integrated circuit. For example, metal filled gaps may be used as a gate fill in a P-type metal oxide semiconductor (PMOS) or complementary metal oxide semiconductor (CMOS) integrated circuit or in a source/drain trench contact.

The gaps may also be arranged in a horizontal direction in already manufactured layers. Again, the gaps may have a high aspect ratio in that their depth, now in the horizontal direction, is much larger than their width. Gaps in the horizontal direction and filled with a metal may, for example, be used in a word line of a memory integrated circuit of the 3D NAND type. The gaps may also be arranged in a combination of vertical and horizontal directions.

The surface of the gaps may comprise one sort of deposited material. Alternatively, the surface of the gaps may comprise different sorts of deposited material. The surface of the gaps may, for example, comprise aluminum oxide and/or titanium nitride. When, for example, a molybdenum conductive layer may be required in the gaps it may be difficult to deposit the molybdenum on the different material in the gaps. It may be required that the molybdenum layers may be covering the full surface of the gaps and fill the complete gap. Further, it may be required that the molybdenum layers may be covering the full surface of the gaps including the different sorts of material.

To fill the complete gap, a seed layer may be deposited in the gap and a bulk layer may be deposited on the seed layer. The seed layer may be formed by sequentially repeating a pretreatment atomic layer deposition (ALD) cycle. Alternatively, the seed layer may be formed by a chemical vapor deposition (CVD) process. The CVD process may be pulsed wherein the first precursor is supplied with pulses onto the substrate while continuously supplying the first reactant to the substrate or the other way around. The bulk layer may be deposited on the seed layer by sequentially repeating a bulk ALD cycle. Alternatively, the bulk layer may be deposited on the seed layer by a CVD process. The CVD process may be pulsed wherein the second precursor is supplied with pulses onto the substrate while continuously supplying the second reactant to the substrate or the other way around.

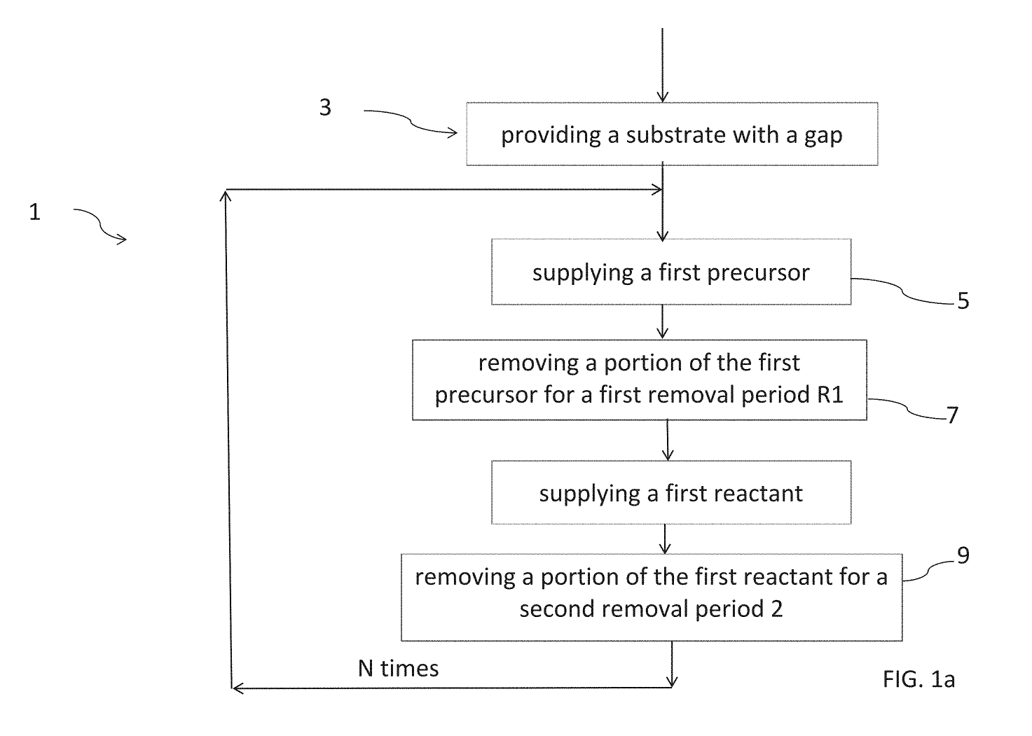

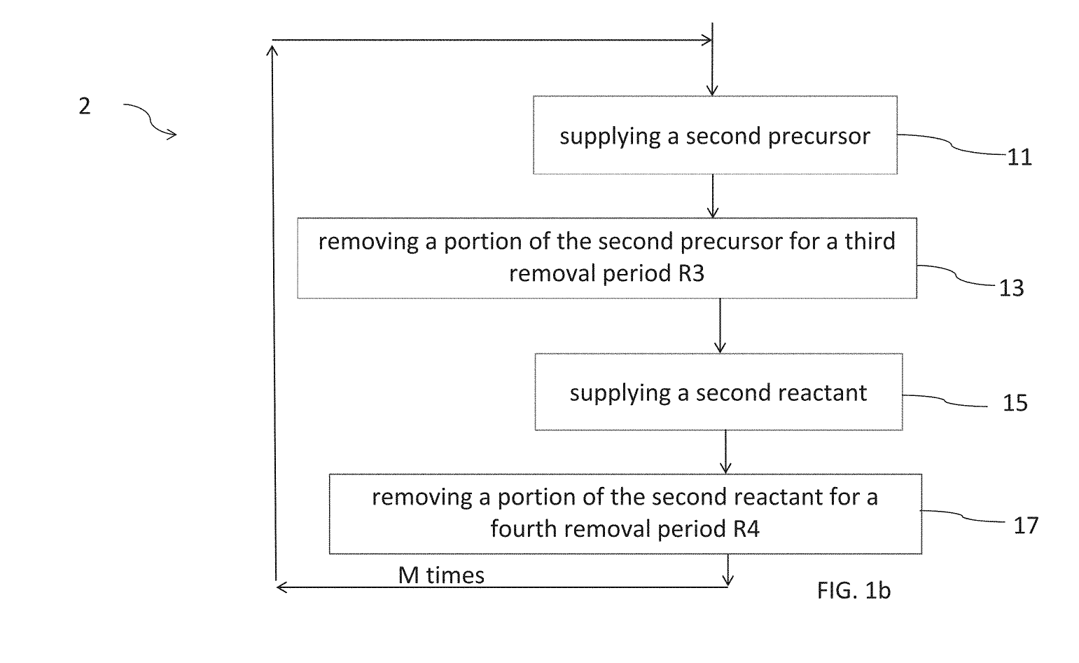

FIGS. 1a and 1b show a flowchart illustrating a method of depositing a layer according to an embodiment wherein a seed layer may be deposited in the gap and a bulk layer may be deposited on the seed layer. A pretreatment ALD cycle 1 for the seed layer may be shown in FIG. 1a and a bulk ALD cycle 2 for the bulk layer may be shown in FIG. 1b.

After providing a substrate with a gap in step 3 in a reaction chamber a first precursor comprising metal and halogen atoms may be supplied to the substrate in step 5 for a first supply period T1 (see FIG. 1a). Subsequently, additional supply of the first precursor to the substrate may be stopped, for example, by removing, e.g., purging, a portion of the first precursor from the reaction chamber for a first removal period R1 in step 7. Further, the cycle may comprise supplying 9 a first reactant to the substrate for a second supply period T2. A portion of the first precursor and first reactant may react to form at least a portion of the seed layer on the substrate. Normally, it may take a few (around 50) cycles before deposition of the seed layer starts. Additional supply of the first reactant to the substrate may be stopped, for example, by removing, e.g., purging a portion of the first reactant from the reaction chamber for a second removal period R1 in step 11.

The first precursor and the first reactant may be selected to have a proper nucleation on the surface of the gaps. The pretreatment ALD cycle 1 may be repeated N times to deposit the seed layer with N selected between 100 and 1000, preferably 200 and 800, and more preferably 300 and 600. The seed layer may have a thickness between 1 and 20, preferably 2 and 10, more preferably between 3 and 7 nm.

After the pretreatment, ALD cycle 1 is repeated N times. A second precursor comprising metal and halogen atoms may be supplied to the substrate in step 11 for a third supply period T3 in the bulk ALD cycle 2 (see FIG. 1b). This may be done in the same reaction chamber as the pretreatment ALD cycle 1 of FIG. 1a or in a different reaction chamber. It may be advantageous to do the bulk ALD cycle in a different reaction chamber than the pretreatment ALD cycle when the temperature requirement for the pretreatment cycle may be different. A substrate transfer may therefore be necessary. Subsequently, additional supply of the second precursor to the substrate may be stopped, for example, by removing, e.g., purging a portion of the second precursor from the reaction chamber for a third removal period R3 in step 13.

Further, the cycle may comprise supplying 15 a second reactant to the substrate for a fourth supply period T4. A portion of the second precursor and the second reactant may react to form at least a portion of the bulk layer on the substrate. Additional supply of the second reactant to the substrate may be stopped, for example, by removing, e.g., purging a portion of the second reactant from the reaction chamber for a fourth removal period R4 in step 17. The second precursor and the second reactant may be selected to have proper electronical properties. For example, to have a low electric resistivity. The molybdenum film may have an electrical resistivity of less than 3000 μΩ-cm, or less than 1000 μΩ-cm, or less than 500 μΩ-cm, or less than 200 μΩ-cm, or less than 100 μΩ-cm, or less than 50 μΩ-cm, or less than 25 μΩ-cm, or less than 15 μΩ-cm or even less than 10 μΩ-cm.

The bulk ALD cycle 2 for the bulk layer may be repeated M times with M selected between 200 and 2000, preferably 400 and 1200, and more preferably 600 and 1000. The bulk layer may have a thickness between 1 and 100, preferably 5 and 50, more preferably between 10 and 30 nm.

The first and second precursor may comprise the same metal atom. The metal may be a transition metal atom. The transition metal atom may be molybdenum.

The first and second precursor may comprise the same halogen atom. The halogen atom may be a chloride. By having the same halogen the qualification of the tool and the process in the fab may be simplified since only one halogen may need to be assessed. The first precursor may comprise molybdenum pentachloride (MoCl₅).

The process temperature in the reaction chamber may be selected to be between 300 and 800, preferably 400 and 700, and more preferably 450 and 550° C. during the pretreatment ALD cycle. The vessel in which the first precursor is vaporized may be maintained between 40 and 100, preferably 60 and 80, and more preferably around 70° C.

The second precursor may comprise an additional atom not being a metal or halogen atom. The additional atom may be a chalcogen. The chalcogen may be oxygen, sulfur, selenium or tellurium. The second precursor may comprise molybdenum (VI) dichloride dioxide (MoO₂Cl₂).

The process temperature may be between 300 and 800, preferably 400 and 700, and more preferably 500 and 650° C. during the bulk ALD cycle. The vessel in which the second precursor is vaporized may be maintained between 20 and 150, preferably 30 and 120, and more preferably 40 and 110° C.

Supplying the first and/or second precursor into the reaction chamber may take a duration T1, T3 selected between 0.1 and 10, preferably 0.5 and 5, and more preferably 0.8 and 2 seconds. For example, T1 may be 1 second and T3 may be 1.3 seconds. The flow of the first or second precursor into the reaction chamber may be selected between 50 and 1000, preferably 100 and 500, and more preferably 200 and 400 sccm. The pressure in the reaction chamber may be selected between 0.1 and 100, preferably 1 and 50, and more preferably 4 and 20 Torr.

One or both of the first and second reactants may have hydrogen atoms. At least one of the first and second reactant may comprise hydrogen (H₂). The first and second reactant may be the same. Supplying the first and/or second reactant into the reaction chamber for a duration T2, T4 may take between 0.5 and 50, preferably 1 and 10, and more preferably 2 and 8 seconds. The flow of the first or second reactant into the reaction chamber may be between 50 and 50000, preferably 100 and 20000, and more preferably 500 and 10000 sccm.

Silane may be considered for the first and/or second reactant. The general formula for silane is SiₓH2₍ₓ₊₂₎ where x is an integer 1, 2, 3, 4 . . . Silane (SiH₄), disilane (Si₂H₆) or trisilane (Si₃H₈) may be suitable examples for the first and or second reactant having hydrogen atoms.

Removing, e.g., purging a portion of at least one of the first precursor, the first reactant, the second precursor and the second reactant from the reaction chamber for a duration R1, R2, R3 or R4 may be done between 0.5 and 50, preferably 1 and 10, and more preferably 2 and 8 seconds. Purging may be used after supplying the first precursor to the substrate; after supplying the first reactant to the substrate; after supplying the second precursor to the seed layer; and after supplying the second reactant to the seed layer to remove a portion of at least one of the first precursor, the first reactant, the second precursor and the second reactant from the reaction chamber for a duration R1, R2, R3 or R4. Removing may be accomplished by pumping and/or by providing a purge gas. The purge gas may be an inert gas such as nitrogen.

The method may be used in a single or batch wafer ALD apparatus. The method comprising providing the substrate in a reaction chamber and the pretreatment ALD cycles in the reaction chamber may comprise: supplying the first precursor to the substrate in the reaction chamber; purging a portion of the first precursor from the reaction chamber; supplying the first reactant to the substrate in the reaction chamber; and purging a portion of the first reactant from the reaction chamber. Further the method comprises providing the substrate in a reaction chamber and the bulk ALD cycles in the reaction chamber comprises: supplying the second precursor to the substrate in the reaction chamber; purging a portion of the second precursor from the reaction chamber; supplying the second reactant to the substrate in the reaction chamber; and purging a portion of the second reactant from the reaction chamber.

Exemplary single wafer reactors, designed specifically to perform ALD processes, are commercially available from ASM International NV (Almere, The Netherlands) under the tradenames Pulsar®, Emerald®, Dragon® and Eagle®. The method may also be performed in a batch wafer reactor, e.g., a vertical furnace. For example, the deposition processes may be performed in an A412™ vertical furnace available from ASM International NV as well. The furnace may have a process chamber that can accommodate a load of 150 semiconductor substrates, or wafers, having a diameter of 300 mm.

The wafer reactors may be provided with a controller and a memory which may control the reactor. The memory may be programmed with a program to supply the precursors and the reactants in the reaction chamber in accordance with the embodiments of this disclosure when executed on the controller.

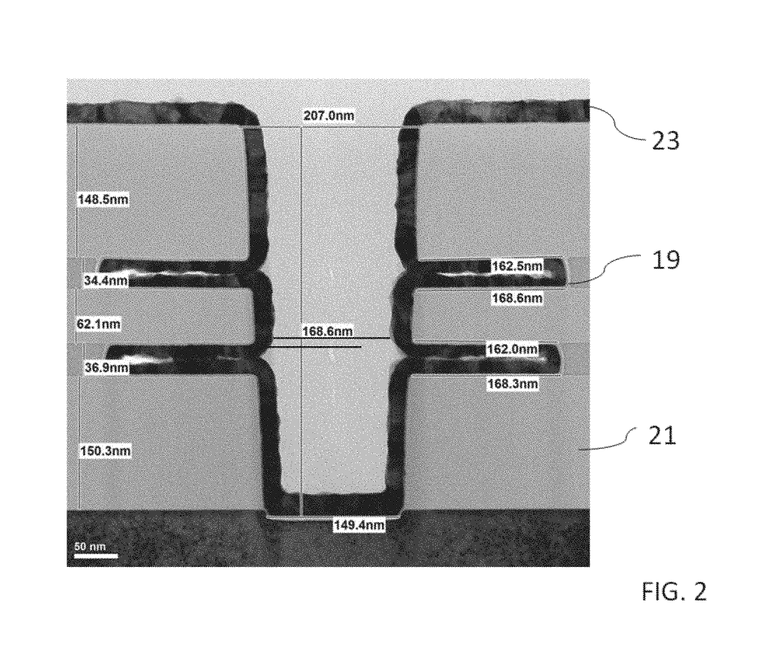

FIG. 2 shows a cross-section of a gap structure on a substrate filled with a layer according to an embodiment of this disclosure. As shown the gap may be extending vertically and horizontally in already manufactured layers having a substantially horizontal top surface.

The gaps may have a high aspect ratio in that the depth vertically and or horizontally is much larger than the width. For example, in the vertical direction the gap has a width of 207 nm at the top, 169 nm in the middle and 149 nm at the bottom while the depth of the gap is much larger with 432 nm. For example, in the horizontal direction the first gap from the top has a width of 34 nm while the depth of the gap is much larger with 163 nm (rounded off). The aspect ratios (gap depth/gap width) of the gap may be more than about 2, more than about 5, more than about 10, more than about 20, more than about 50, more than about 75 or in some instances even more than about 100 or more than about 150 or more than about 200.

It may be noted that the aspect ratio may be difficult to determine for the gap, but in this context the aspect ratio may be replaced by the surface enhancement ratio which may be the ratio of the total surface area of the gap in the wafer or part of the wafer in relation to the planar surface area of wafer or part of the wafer. The surface enhancement ratio (surface gaps/surface wafer) of the gap may be more than about 2, more than about 5, more than about 10, more than about 20, more than about 50, more than about 75 or in some instances even more than about 100 or more than about 150 or more than about 200.

The surface of the gaps may comprise different sorts of deposited material 19, 21. The surface may, for example, comprise Al₂O₃ or TiN.

A conformal metal layer 23 is deposited on the surface of the gap by depositing a seed layer by sequentially repeating a pretreatment ALD cycle with a first precursor and depositing a bulk layer by sequentially repeating a bulk ALD cycle with a second precursor. Details of the used method are shown in FIGS. 1a and 1b and the related description. In some embodiments, a deposited film comprising Mo may have a step coverage greater than about 50%, greater than about 80%, greater than about 90%, greater than about 95%, greater than about 98%, greater than about 99%.

The first and second precursor may comprise the same metal atom, for example, a transition metal atom such as molybdenum. The first and second precursor may comprise the same halogen atom, for example, a chloride. The first precursor may comprise MoCl5. The second precursor may comprise an additional atom not being a metal or halogen atom, for example, a chalcogenide atom such as oxygen. The second precursor may comprise molybdenum(VI) dichloride dioxide (MoO₂Cl₂). The method may be performed in an atomic layer deposition apparatus. For example, the deposition processes may be performed in an EMERALD® XP ALD apparatus.

The first and second reactants were hydrogen (H₂) which was supplied in the reaction chamber for a duration T2, T4 of 5 seconds with a flow of 495 sccm. A purge gas of nitrogen was used after supplying the first precursor; after supplying the first reactant; after supplying the second precursor; and after supplying the second reactant for a duration R1, R2, R3 or R4 of 5 seconds.

The process temperature was around 550° C. and the pressure was around 10 Torr during the pretreatment and bulk ALD cycles. The vessel in which the first precursor was vaporized was around 70° C. The vessel in which the second precursor was vaporized was around 35° C.

A seed layer of about 4.6 nm was deposited using the pretreatment ALD cycle for 500 cycles and a bulk layer of about 21.4 nm was deposited using the bulk ALD cycle for 800 cycles. As shown the molybdenum layer 23 is deposited very uniformly over the surface of the gap and had a total thickness of about 26 nm.

The orientation of the gap, whether it is horizontal or vertical and the width of the gap doesn't seem to influence the thickness of the layer 23 substantially. Further the material of the surface whether it is Al₂O₃ 19 or TiN 21 doesn't seem to influence the thickness of the layer 23 either. In this way it becomes possible to create metal filled gaps with a good uniformity.

The method may also be used in a spatial atomic layer deposition apparatus. In spatial ALD, the precursor and reactant are supplied continuously in different physical sections and the substrate is moving between the sections. There may be provided at least two sections where, in the presence of a substrate, a half-reaction can take place. If the substrate is present in such a half-reaction section a monolayer may form from the first or second precursor. Then, the substrate is moved to the second half-reaction zone, where the ALD cycle is completed with the first or second reactant to form one ALD monolayer. Alternatively the substrate position could be fixed and the gas supplies could be moved, or some combination of the two. To obtain thicker films, this sequence may be repeated.

According to an embodiment in a spatial ALD apparatus, the method comprises:

placing the substrate in a reaction chamber comprising a plurality of sections, each section separated from adjacent sections by a gas curtain;

supplying the first precursor to the substrate in a first section of the reaction chamber;

laterally moving the substrate surface with respect to the reaction chamber through a gas curtain to a second section of the reaction chamber;

supplying the first reactant to the substrate in the second section of the reaction chamber to form the seed layer;

laterally moving the substrate surface with respect to the reaction chamber through a gas curtain; and

repeating supplying the first precursor and the reactant including lateral movement of the substrate surface with respect to the reaction chamber to form the seed layer.

To form the bulk layer, the method further comprises:

placing the substrate in a reaction chamber comprising a plurality of sections, each section separated from adjacent sections by a gas curtain;

supplying the second precursor to the substrate in a first section of the reaction chamber;

laterally moving the substrate surface with respect to the reaction chamber through a gas curtain to a second section of the reaction chamber;

supplying the second reactant to the substrate in the second section of the reaction chamber to form the bulk layer;

laterally moving the substrate surface with respect to the reaction chamber through a gas curtain; and

repeating supplying the second precursor and the reactant including lateral movement of the substrate surface with respect to the reaction chamber to form the bulk layer.

The first and second precursor may be different. The first and second reactant may be the same and comprise hydrogen atoms.

According to an embodiment, the seed layer may be deposited with a chemical vapor deposition (CVD) process wherein the first precursor and the first reactant are simultaneously supplied to the substrate. The bulk layer may be deposited with a CVD process wherein the second precursor and the second reactant may be simultaneously supplied to the substrate as well.

The CVD processes may be pulsed CVD processes wherein the precursors are supplied with pulses to the substrate while continuously supplying the reactants to the substrate. The advantage may be that the higher concentration of reactant may lower the concentration of the halogens. High concentration of halogens may be damaging for the semiconductor devices on the substrate.

For example, in a pulsed CVD process for the seed layer the first precursor molybdenum pentachloride (MoCl₅) may be provided with pulses of 1 second alternating with a 5 seconds purge gas flow. The first reactant hydrogen may be supplied continuously with a flow rate of 500 sccm and the substrate may be kept at 550° C.

Exemplary single wafer reactors, designed specifically to perform CVD processes, are commercially available from ASM International NV (Almere, The Netherlands) under the tradenames Dragon®. The method may also be performed in a batch wafer reactor, e.g., a vertical furnace. For example, the deposition processes may be performed in an A400™, or A412™ vertical furnace available from ASM International NV as well. The furnace may have a process chamber that can accommodate a load of 150 semiconductor substrates, or wafers.

For the production of 3D NAND memory, a word line may have a gap which requires a low resistivity metal fill. Existing solutions may utilize TiN as a seed layer for a CVD tungsten gap-fill. For the current fluorine based tungsten deposition processes, fluorine from the WF6 precursor may diffuse. A thick (=3 nm) TiN barrier may be necessary to prevent fluorine diffusion and attack of high-k Al2O3 film by the diffused fluorine. However, the high resistivity of the TiN film (800 μΩ-cm at 3 nm) results into an increased TiN/W stack resistivity which may be unwanted.

There may be a need for an improved method to form a deposited layer on a substrate having a low resistivity while being fluorine free. Accordingly, there may be provided a method of forming a layer, comprising: providing a substrate with gaps created during manufacturing of a feature; depositing a seed layer on the substrate; and depositing a bulk layer on the seed layer. Depositing the bulk layer may comprise: supplying a second precursor comprising a transition metal such as tungsten to deposit the bulk layer on top of the seed layer.

The second precursor may comprise a halogen such as a chloride to deposit the bulk layer. The second precursor may be tungsten (V) pentachloride (WCl₅) or tungsten (VI) hexachloride (WCl₆). The bulk layer may be deposited by the reaction of tungsten (V) pentachloride (WCl₅) or tungsten (VI) hexachloride (WCl₆) with hydrogen H₂ in an ALD or CVD mode of operation. The reaction of, for example, WCl₅ may be accomplished at a temperature of 450° C. and a pressure of 40 Torr. The precursors may be provided in ALD or CVD mode of operation.

The seed layer may be deposited with a molybdenum comprising first precursor reacting with hydrogen. The resistivity of the seed layer using molybdenum may be 107 μΩ-cm at 3 nm) which is lower than the TiN layer. In particular for a stack thickness of 15 nm (equivalent to gap-fill in 30 nm CD structures) a good gap-fill was achieved using this approach. By using tungsten (V) pentachloride (WCl₅) or tungsten (VI) hexachloride (WCl₆) to deposit the bulk layer on top of the seed layer it becomes possible to deposit the tungsten layer without using fluorine and still having a low resistivity. The precursor for the seed layer may comprise a transition metal (e.g., molybdenum (Mo)), a halogen (e.g., a chloride (Cl)) and optional a chalcogenide (e.g., an oxygen (O)). The precursor for the seed layer may, for example, be pentachloride (MoCl₅) or molybdenum (VI) dichloride dioxide (MoO₂Cl₂) both are reacting with hydrogen. The partial pressure of hydrogen may be 100 times lower if molybdenum pentachloride (MoCl₅) is used with respect to molybdenum (VI) dichloride dioxide (MoO₂Cl₂).

The deposition speed of the molybdenum seed layer may be 1.2 angstrom per cycle. For comparison the deposition speed of the TiN seed layer may be 0.6 angstrom per cycle under the same circumstances. The deposition speed of the molybdenum seed layer may therefore be sufficient.

The metal deposited on the seed layer may be copper. The second precursor may comprise copper. The second precursor may comprise a halogen such as a chloride to deposit the bulk layer. The second precursor may comprise copper (II) dichloride (CuCl₂) or copper chloride (CuCl). The precursors may be provided in ALD or CVD mode of operation reacting with hydrogen.

The metal deposited on the seed layer may be a transition or noble metal from the group of: Ti, V, Cr, Mn, Nb, Mo, Ru, Rh, Pd, Ag, Hf, Ta, W, Re, Os, Ir and Pt. In some embodiments the layer may comprise Co or Ni.

In additional embodiments, the seed or bulk layer may comprise less than about 40 at. %, less than about 30 at. %, less than about 20 at. %, less than about 10 at. %, less than about 5 at. %, or even less than about 2 at. % oxygen. In further embodiments, the seed or bulk layer may comprise less than about 30 at. %, less than about 20 at. %, less than about 10 at. %, or less than about 5 at. %, or less than about 2 at. %, or even less than about 1 at. % of hydrogen. In some embodiments, the seed or bulk layer may comprise halide or chloride less than about 10 at. %, or less than about 5 at. %, less than about 1 at. %, or even less than about 0.5 at. %. In yet further embodiments, the seed or bulk layer may comprise less than about 10 at. %, or less than about 5 at. %, or less than about 2 at. %, or less than about 1 at. %, or even less than about 0.5 at. % carbon. In the embodiments outlined herein, the atomic percentage (at. %) concentration of an element may be determined utilizing Rutherford backscattering (RBS).

In some embodiments of the disclosure, forming a semiconductor device structure, such as semiconductor device structure, may comprise forming a gate electrode structure comprising a molybdenum film, the gate electrode structure having an effective work function greater than approximately 4.9 eV, or greater than approximately 5.0 eV, or greater than approximately 5.1 eV, or greater than approximately 5.2 eV, or greater than approximately 5.3 eV, or even greater than approximately 5.4 eV. In some embodiments, the effective work function values give above may be demonstrated for an electrode structure comprising a molybdenum film with a thickness of less than approximately 100 Angstroms, or less than approximately 50 Angstroms, or less than approximately 40 Angstroms, or even less than approximately 30 Angstroms.

It will be appreciated by those skilled in the art that various omissions, additions and modifications can be made to the processes and structures described above without departing from the scope of the invention. It is contemplated that various combinations or sub-combinations of the specific features and aspects of the embodiments may be made and still fall within the scope of the description. Various features and aspects of the disclosed embodiments can be combined with, or substituted for, one another in order. All such modifications and changes are intended to fall within the scope of the invention, as defined by the appended claims.

What is claimed is:

1. A method of forming a layer, comprising:
providing a substrate with gaps created during manufacturing of a feature;
depositing a seed layer on the substrate; and
depositing a bulk layer on the seed layer,
wherein depositing the seed layer comprises:
supplying a first precursor comprising metal and halogen atoms to the substrate; and
supplying a first reactant to the substrate, wherein a portion of the first precursor and the first reactant react to form at least a portion of the seed layer;
wherein depositing the bulk layer comprises:
supplying a second precursor comprising metal and halogen atoms to the seed layer; and
supplying a second reactant to the seed layer, wherein a portion of the second precursor and the second reactant react to form at least a portion of the bulk layer on the seed layer, and
wherein the first and second precursor are different.

2. The method according to claim 1, wherein at least one of the first and second reactant comprises hydrogen atoms.

3. The method according to claim 2, wherein at least one of the first and second reactant comprises hydrogen (H₂).

4. The method according to claim 1, wherein the first and second precursor comprise the same metal atom.

5. The method according to claim 1, wherein at least one of the first and second precursors comprises a transition metal atom.

6. The method according to claim 5, wherein the transition metal atom is molybdenum.

7. The method according to claim 1, wherein the first and second precursor comprise the same halogen atom.

8. The method according to claim 1, wherein the halogen atom is chloride.

9. The method according to claim 1, wherein the first precursor comprises molybdenum pentachloride (MoCl₅).

10. The method according to claim 1, wherein the second precursor comprises an additional atom not being a metal or halogen atom.

11. The method according to claim 10, wherein the additional atom is a chalcogenide.

12. The method according to claim 11, wherein the chalcogenide is oxygen.

13. The method according to claim 12, wherein the second precursor comprises molybdenum(VI) dichloride dioxide (MoO₂Cl₂).

14. The method according to claim 1, wherein at least one of the first and second precursor is supplied with pulses into the reaction chamber and the pulses are between 0.1 and 10 seconds.

15. The method according to claim 1, wherein the flow of the first or second precursor into the reaction chamber is between 50 and 1000 sccm.

16. The method according to claim 1, wherein the flow of the first or second reactant into the reaction chamber is between 50 and 50000 sccm.

17. The method according to claim 1, wherein the pressure in the reaction chamber is between 0.1 and 100 Torr.

18. The method according to claim 1, wherein the process temperature is between 300 and 800° C.

19. The method according to claim 1, wherein depositing at least one of the seed and bulk layer comprises repeating an atomic layer deposition (ALD) cycle comprising sequentially supplying the first or second precursor to the substrate; and supplying the first or second reactant to the substrate.

20. The method according to claim 19, wherein in between supplying the first precursor, the first reactant, the second precursor or the second reactant to the substrate the substrate is purged between 0.5 and 50 seconds.

21. The method according to claim 19, wherein supplying the first and/or second reactant into the reaction chamber takes between 0.5 and 50 seconds.

22. The method according to claim 19, wherein for depositing the seed layer a pretreatment ALD cycle is repeated between 100 and 1000 times and for depositing the bulk layer the bulk ALD cycle is repeated between 200 and 2000 times.

23. The method according to claim 1, wherein depositing at least one of the seed and bulk layer comprises a chemical vapor deposition (CVD) process wherein the precursor is supplied simultaneously with the reactant to the substrate.

24. The method according to claim 5, wherein the transition metal is tungsten (W).

25. The method according to claim 1, wherein the second precursor comprises tungsten (W).

26. The method according to claim 25, wherein the second precursor comprises tungsten (V) pentachloride (WCl₅) or tungsten (VI) hexachloride (WCl₆).

27. The method according to claim 1, wherein the second precursor comprises copper.

28. The method according to claim 24, wherein the second precursor comprises copper (II) dichloride (CuCl₂) or copper chloride (CuCl).
